(19) United States
(12) Patent Application Publication
(10) Pub. No.: US 2007/0217266 A1
(43) Pub. Date: Sep. 20, 2007

(54) Static random access memory

(76) Inventor: Juhan Kim, San Jose, CA (US)

Correspondence Address: JUHAN KIM, 5890 W. WALBROOK DR., SAN JOSE, CA, 95129, US

(21) Appl. No.: 11/757,493

(22) Filed: Jun. 4, 2007

Related U.S. Application Data
(63) Continuation of application No. 11/755,197, filed on May 30, 2007.
Application No. 11/755,197 is a continuation of application No. 11/164,919, filed on Dec. 11, 2005, now Pat. No. 7,196,926.

(51) Int. Cl. G11C 16/06

(52) U.S. Cl. 365/185.21

(57) ABSTRACT

SRAM cell includes a four-terminal diode as a read device wherein the first terminal is connected to a read word line, the second terminal is connected to a storage device through a resistor, the third terminal is floating, and the fourth terminal is connected to one of two bit lines; and two MOS transistors as a write device; and each MOS transistor is connected to the bit line respectively; and a latch including two cross-coupled inverters as the storage device; and the SRAM cell can be formed from thin-film layer, thus multiple memory cells are stacked; and the heavy routing lines are driven by the bipolar drivers which are part of the invention, hence the bipolar circuits and the control MOS transistors of the peripheral circuit can be formed from the deposited thin-film layers; consequently the whole chip can be stacked over the wafer, such as silicon, quartz and others; additionally it applications are extended to a multi port memory and a content addressable memory.

### CROSS REFERENCE TO RELATED APPLICATION

The present invention is a continuation of application Ser. No. 11/755,197, filed on May 30, 2007, which is a continuation of application Ser. No. 11/164,919, filed on Dec. 11, 2005, now U.S. Pat. No. 7,196,926, which are herein incorporated by reference.

### FIELD OF THE INVENTION

The present invention relates generally to integrated circuits, in particular to SRAM (Static Random Access Memory) including a static storage element, and its applications, such as single port memory, multi port memory and CAM (content addressable memory).

### BACKGROUND OF THE INVENTION

A p-n-p-n diode known as Shockley diode or thyristor, is a solid-state semiconductor device similar to two-terminal p-n diode, with an extra terminal which is used to turn it on. Once turned on, diode (p-n-p-n diode or n-p-n-p diode) will remain on conducting state as long as there is a significant current flowing through it. If the current falls to zero, the device switches off. Diode has four layers, with each layer consisting of an alternately p-type or n-type material, for example p-n-p-n and n-p-n-p. The main terminals, labeled anode and cathode, are across the full four layers, and the control terminal, called the gate, is attached to one of the middle layers. The operation of a diode can be understood in terms of a pair of tightly coupled transistors, arranged to cause the self-latching action.

Diodes are mainly used where high currents and voltages are involved, and are often used to control alternating currents, where the change of polarity of the current causes the device to automatically switch off; referred to as ‘zero cross operation’. The device can also be said to be in synchronous operation as, once the device is open, it conducts in phase with the voltage applied over its anode to cathode junction. This is not to be confused with symmetrical operation, as the output is unidirectional, flowing only from anode to cathode, and so is asymmetrical in nature. These properties are used control the desired load regulation by adjusting the frequency of the trigger signal at the gate. The load regulation possible is broad as semiconductor based devices are capable of switching at extremely high speeds over extremely large numbers of switching cycles.

In FIG. 1A, the schematic of diode is illustrated. It consists of four terminals, such that the anode 111 is connected to power supply or regulating node, the base 112 of p-n-p transistor 115 serves as the collector 112 of n-p-n transistor 114, the collector 113 of p-n-p transistor 115 serves as the base of n-p-n transistor 114 which is controlled by the voltage controller 116. In order to turn on diode and hold the state of turn-on, the voltage controller should raise the voltage from ground level to VF (forward bias, 0.6 v˜0.8 v for silicon). And the voltage controller 116 should supply the current 117, referred as the base current, which current depends on the characteristic of transistor 114 and 115. Once the base current 117 establishes the forward bias (VF), the collector 112 of n-p-n transistor 114 holds the current path 119 from the base of p-n-p transistor 115. After then, p-n-p transistor 115 is turned on because the base 112 has forward bias from the emitter 111. This makes the current path 118 which can keep the turn-on state. This is the holding state as long as the base has not so much leakage to drive the base voltage under forward bias (VF) even though the voltage controller 116 is open. To turn off diode, the voltage controller 116 should lower the voltage of the base of n-p-n transistor 114 under forward bias. To do so, the voltage controller 116 should (negatively) flow more current than the current path 118.

The diode is mainly used for the high voltage regulation, but the MOS transistor is used for the memory operation in general because of the simplicity of the MOS transistor as an access device. However, fabricating the MOS transistor will be reached to the scaling limit in the near future, and also the process cost will be extremely expensive with smaller feature size, such 45 nm, 32 nm and 22 nm. In the present invention, sophisticated circuit techniques are introduced in order to improve the memory operation with a four-terminal diode as a read device. With this method, there is no need of extreme feature size device with multi-stacked devices. Furthermore, there are no new materials are required to fabricate the new generation semiconductor memory chip. Before explaining the present invention, there is a need to review the conventional SRAM as a prior art.

The conventional SRAM is illustrated in FIG. 1B as a prior art, U.S. Pat. No. 6,683,805, No. 5,320,975, No. 5,616,934, No. 5,734,179, No. 7,151,696, and WIPO WO/2006/100641, as published, wherein the MOS access transistors 153 and 158 serve as a read device and also a write device, and a latch including two cross-coupled inverters 155 and 156 serves as a storage device. Thus, six MOS transistors are used to configure a memory cell, which is the major drawback of the conventional SRAM because it occupies relatively wider area than other types of memories, such as DRAM. When read, by asserting the word line 151 to high, the stored charges in the storage node 154 and 157 are transferred to the bit lines 152 and 159 respectively, but the bit lines are heavily loaded with multiple memory cells and relatively long metal line. In order to achieve fast read operation, all six MOS transistors should be high-performance devices, but the MOS transistors in the latch should be low-performance device for fast flipping during write operation, because the latch should be flipped by the bit lines. When the MOS transistors of the latch are too strong, the flipping is very slow or failed, while the read operation is relatively fast. And one more major drawback is that fabricating the high-performance MOS transistor on the surface of the wafer reaches to the scaling limit in the near future, such that smaller than 22 nm MOS transistor is more challenging with the existing materials and less economical.

And there are many efforts to improve the conventional SRAM, with introducing new circuit concepts, such that five or four transistor memory cell are reported, U.S. Pat. No. 6,291,276 and U.S. Pat. No. 7,180,768. Furthermore, three or two MOS transistor memory cells are published, U.S. Pat. No. 7,098,472 and U.S. Pat. No. 5,543,652. However, the read path still includes the high-performance MOS transistor and also the MOS transistor serves as a write device, in order to drive heavily loaded bit line for the fast access.

As reviewed, the conventional SRAM and other prior arts use the bi-directional MOS transistor as a read device and also a write device, because it is straightforward to access the storage device directly. However, the bi-directional traffic is generally slow. In this respect, the read path and the write path can be separately controlled as the express way has two way traffics with traffic signal in the street. And a small storage device controls the strong diode read device when read, as a small car key can start several hundred horse power engine with two fingers (or three fingers may be available, but the whole body is not necessary). One more aspect is the memory cells are stacked over the control circuits, and multiple memory cells are stacked, as the multi-story building has more rooms on the ground, and the ground is a supporter for the building.

The major improvement of the present invention is that the read access device is very strong, while the write device is relatively weak. Furthermore, the active power is dramatically reduced by removing the current loading, during read and write operations. In this manner, the bit line current loading is two or three because the delay signal sequentially enables the current path of the bit lines in the memory array when read. Furthermore, the read path uses a four-terminal diode which drives the heavily loaded bit line with strong current flow, and the write path uses the thin-film MOS transistor so that the flipping the inverter latch is faster because the latch is much weaker than the bit line driver circuit when write, thus the write current is reduced and the leakage is reduced with weak latches. And the standby current is also reduced with weak latch device as a storage element.

In the present invention, sophisticated circuit techniques are introduced to control the read path and the write path separately, so that the four-terminal diode is used as a read access device and the (weak) MOS transistor is still used as a write device, and relatively weak inverters serve as a storage device. Furthermore, the four-terminal diode serves as a sense amplifier as well, such that the diode output generates information “on” or “off” which is digital value. It gives as many as advantages to design and fabricate it. However the diode operation is not as simple as the MOS transistor because it has unidirectional current control characteristic and internal feedback loop.

Separately a latch is still required to store data as the conventional SRAM, but now there is no need of high performance inverter latch to drive the bit line directly. Instead, the inverter latch drives only one of diode terminals through a resistor, which diode terminal has very little capacitance, and the inverter latch indirectly communicates to the bit line (or data line), while diode directly communicates to the bit line during read. As a result, the diode serves as a sense amplifier to detect whether the storage node voltage is forward bias or not. This is different control method from the conventional SRAM, where the gate of MOS transistor is connected to the word line and turns on and off, but the load of the word line is only gate and routing capacitance, while the storage inverter drives very heavy bit line directly, which means that the word line loading is very light, in the conventional SRAM. Conversely, using diode as a read access device gives the bit line loading to the read word line through the diode, which makes the read word line loading very heavy, but it is controllable to design with strong driver or segmentation for the read word line. Even though the read word line loading is high, it is desirable to configure a memory array because the read word line driver is stronger than the weak storage inverter.

Furthermore, the MOS write device can be a coarse device such as thin-film transistor because the MOS transistor drives only a small storage inverter, which ensures that the memory cells are formed in between the routing layers. In doing so, there is no high performance MOS transistor in the memory cell, and one more improvement is that the bipolar transistors can be used as internal buffers such as the word line driver and the bit line driver. In addition, the output driver can use the similar type of bipolar buffer circuit.

And one of major advantages of the present invention is that there is no need of extreme feature size transistors because the memory cells can be stacked over the control circuit. In stead of scaling the transistors to extreme geometry, topping more memory cells are practical, which also achieves fast access with centralized control and short routing length in vertical direction. As a result, there is no scaling limit to fabricate the memory chip by topping multiple memory cells.

The heavily loaded control signals are driven by bipolar buffers which are also formed from the thin-film layers. This means that the control circuits can be stacked over the wafer with an insulator because there is no need for fabricating high-performance MOS transistor on the surface of the wafer. Consequently, the whole chip can be fabricated on the isolation layer on the wafer. In doing so, the wafer serves only as a supporter. Thus, any types of wafer can be a supporter to reduce the wafer cost, such as low purity silicon wafer, quartz wafer, ceramic wafer, glass, metal and so on.

### SUMMARY OF THE INVENTION

In the present invention, static random access memory including a four-terminal diode read device and its applications are described, wherein the four-terminal diode serves as a read access device, two MOS transistors serve as write device and two small inverter latch store the voltage data. More specifically, during read operation, the read word line is asserted to activate the diode, while the write word line serves as a gate of the write MOS transistors and the gate turns off the write MOS transistor. In contrast, the write word line is asserted to write the charge to the latch node during write operation, while the read word line is de-asserted.

The memory cells can be formed within the current CMOS process environment, but with no new material. Thus, the peripheral circuits and the memory cells can be formed on the conventional wafer, such as the bulk wafer and the SOI wafer. Furthermore, one of major improvement of the present invention is that the memory cells can be formed in between the routing layers in order to reduce chip area, and also the memory cells can be stacked over the control circuits including MOS transistors where the memory cells are composed of the thin-film transistor such as polysilicon and amorphous silicon with low temperature process. The read diode need not be a high performance device nor have a high current gain, because the current path of diode includes its whole junction area while the current path of MOS transistor includes a shallow inversion layer on the surface by the electric field. Thus, the current gain of the diode is much higher than that of the MOS transistor. The write MOS transistor need not be a high performance device nor have a high current gain either. During write, the write MOS transistor drives only a small storage inverter only, which means that the write MOS device can be a coarse MOS transistor, such as polysilicon or amorphous thin-film MOS transistor. In this manner, the coarse MOS transistor serves as a good write device. In addition, multiple memory cells can be stacked. Hence, topping the memory cells with low temperature is independent on fabricating the control circuits.

The heavily loaded lines are driven by the bipolar output drivers, and the MOS transistor drive only lightly loaded signals. This means that the control circuits can be stacked over the wafer with an insulator because there is no need for fabricating high-performance MOS transistor on the surface of the wafer, where the strong bipolar buffers also formed from the thin-film layers. In doing so, the wafer only serves as a supporter while the conventional MOS transistors use the surface of the wafer, which means that the MOS transistors for the memory control and the memory cells are formed from the deposited polysilicon or amorphous silicon. Thus, any types of wafer can be a supporter in order to reduce the wafer cost. In this respect, there is no need of extreme feature size transistors because the memory cells can be stacked over the control circuit, and the control circuits can be stacked over the any type of wafer. In stead of scaling the transistors, multiple toppings are more meaningful, which also achieves fast access with centralized control and short routing length in vertical directions. In doing so, the present invention can overcome the scaling limit of the SRAM, because there is almost no limit to stack the memory cells in the vertical direction as long as the flatness is good enough to stack more memory cells.

The latch can be very small device, because the latch does not directly drive the heavily loaded bit line during read, the strong diode drives the bit line in stead of the latch. The memory cell is smaller than that of the conventional SRAM, because no big latch is required for storing the voltage data.

Various types of diode can be used to form the memory cell, such as silicon including solid-state, amorphous and stretchable silicon, germanium, compound semiconductors including GaAs, SiGe, and metal semiconductor diode (Schottky diode), as long as the reverse bias current is controllable.

However the operation of the four-terminal diode is not familiar with the memory operation, because it has unidirectional current control characteristic and internal feedback loop, even though it has almost no parasitic effect. In the present invention, sophisticated circuit techniques are introduced to use a diode as a read access device for the SRAM operation. Moreover, the diode serves as a sense amplifier to detect the voltage of the storage node whether it is forward bias or not, then diode sends binary results to the bit line, and the latch device including the current mirror receives the binary results from the bit line, on or off. The current mirror repeats the amount of current that the memory cell flows, and latches the result. After latching data, the output of the latch device cuts off the current path of the bit line, which reduces active current. And the diode read device realizes fast access time, and does not require reference bit line. Furthermore, dummy cells generate replica delay signals which guarantee internal timing margin and reduce operation cycle time. Furthermore, the diode can flow more current than the MOS transistor. The word line cuts off the holding current during standby. Thus there is no standby current except leakage current, which realizes low power consumption. Furthermore, the applications of the present memory cell are extendable for multi port memory and content addressable memory.

These and other objects and advantages of the present invention will no doubt become obvious to those of ordinary skill in the art after having read the following detailed description of the preferred embodiments which are illustrated in the various drawing figures.

### BRIEF DESCRIPTION OF THE DRAWINGS

The accompanying drawings which are incorporated in and form a part of this specification, illustrate embodiments of the invention and together with the description, serve to explain the principles of the invention.

FIG. 1A illustrates a p-n-p-n diode as a prior art. FIG. 1B depicts the schematic of the conventional SRAM, as prior arts.

FIG. 2 illustrates the basic schematics of SRAM memory cell, according to the teachings of the present invention.

FIG. 3 illustrates a read path including a memory cell and a read data latch, according to the teachings of the present invention.

FIG. 4A illustrates I-V curve of the memory cell, according to the teachings of the present invention. FIG. 4B illustrates I-V curve of conventional bipolar transistor is illustrated as a reference. FIG. 4C illustrates detailed I-V curve in linear scale and FIG. 4D illustrates detailed I-V curve in log scale, according to the teachings of the present invention.

FIG. 5A illustrates more detailed read path, according to the teachings of the present invention.

FIG. 5B illustrates the relationship between voltage and temperature of the memory cell, according to the teachings of the present invention. FIG. 5C illustrates I-V curve of pull-down NMOS transistor, according to the teachings of the present invention. FIG. 5D illustrates I-V curve of the diode access device, according to the teachings of the present invention. And FIG. 5E illustrates I-V curve of pull-up device of row decoder, according to the teachings of the present invention.

FIG. 6A illustrates a timing diagram of read “1” operation, according to the teachings of the present invention. FIG. 6B illustrates a timing diagram of read “0” operation, according to the teachings of the present invention. And FIG. 6C illustrates a sequential read timing, according to the teachings of the present invention.

FIG. 7 illustrates the schematic for sequential read operation, according to the teachings of the present invention.

FIGS. 8A and 8B illustrate equivalent circuit of the read path, according to the teachings of the present invention.

FIG. 9A illustrates the write path, FIG. 9B illustrates the timing diagram for write “1”, and FIG. 9C illustrates the timing diagram for write “0”, according to the teachings of the present invention.

FIGS. 10A and 10B illustrate read-modify circuit including the memory cell, according to the teachings of the present invention.

FIG. 11A illustrates read “0” and modify “1” timing diagram, and FIG. 11B illustrates read “1” and modify “0” timing diagram, according to the teachings of the present invention.

FIG. 12A illustrates a whole read path including the output driver circuit. And FIGS. 12B, 12C, 12D and 12E illustrate related sub-circuits and timings of FIG. 12A, according to the teachings of the present invention.

FIGS. 13A and 13B illustrate alternative configurations, according to the teachings of the present invention.

FIG. 14 illustrates an example of multi-port memory application, according to the teachings of the present invention.

FIG. 15 illustrates an example application for content addressable memory, according to the teachings of the present invention.

FIG. 16 provides a truth table summarizing the logical relationships among various signals for content addressable memory, as shown in FIG. 15.

FIG. 17 illustrates a cross sectional view of the memory cell as shown in FIG. 18A to 18F, according to the teachings of the present invention.

FIGS. 18A, 18B, 18C, 18D, 18E, and 18F illustrate top views of the memory cell in FIG. 17, according to the teachings of the present invention.

FIG. 19 illustrates a cross sectional view of the stacked SRAM on the bulk wafer, according to the teachings of the present invention.

FIG. 20 illustrates a cross sectional view of the stacked SRAM cells on the peripheral circuits, according to the teachings of the present invention.

FIG. 21 illustrates a cross sectional view of the stacked SRAM cells under the peripheral circuits, according to the teachings of the present invention.

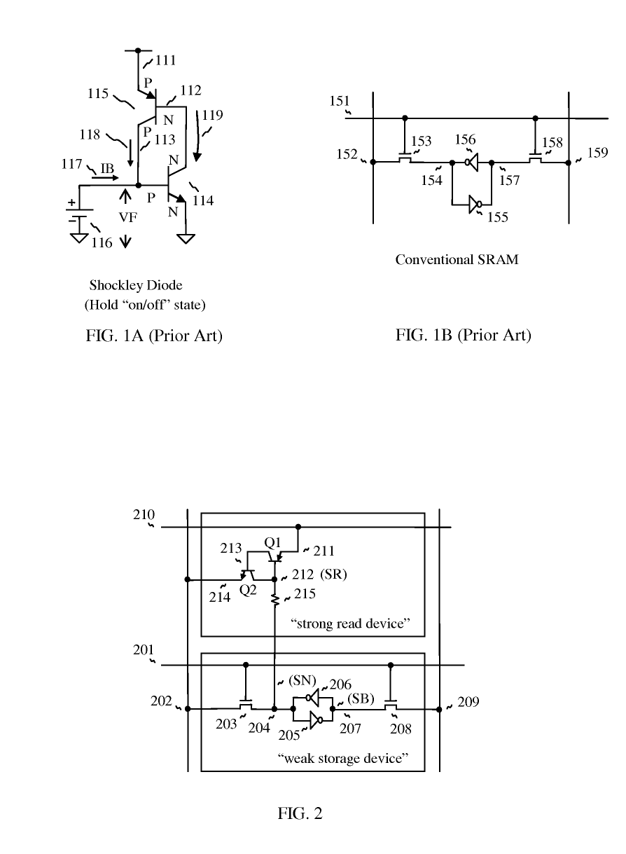

### DETAILED DESCRIPTION OF PREFERRED EMBODIMENT(S)

Reference is made in detail to the preferred embodiments of the invention. While the invention is described in conjunction with the preferred embodiments, the invention is not intended to be limited by these preferred embodiments. On the contrary, the invention is intended to cover alternatives, modifications and equivalents, which may be included within the spirit and scope of the invention as defined by the appended claims. Furthermore, in the following detailed description of the invention, numerous specific details are set forth in order to provide a thorough understanding of the invention. However, as is obvious to one ordinarily skilled in the art, the invention may be practiced without these specific details. In other instances, well-known methods, procedures, components, and circuits have not been described in detail so that aspects of the invention will not be obscured.

The present invention is directed to a static random access memory, as shown in FIG. 2. The SRAM cell includes a diode as a read device wherein the diode includes four terminals, the first terminal 211 is connected to a read word line (RWL) 210, the second terminal 212 is connected to a storage node (SN) 204 of the latch through a resistor 215, the third terminal 213 is floating, and the fourth terminal 214 is connected to the first bit line (BL) 202. Thus, the second terminal 212 serves as a resistor storage node (SR) of the diode. And two MOS transistors as a write device wherein the first MOS transistor 203 is connected to the first bit line 202, the second MOS transistor 208 is connected to the second bit line (BLB) 209, and the gates of MOS write devices serve as a write word line (WWL) 201, and a latch including two cross-coupled inverters 205 and 206 as the storage device, and the first storage node (SN) 204 is connected to the first MOS transistor 203 and the second storage node (SB) 207 is connected to the second MOS transistor 208.

In FIG. 3, a read path including the memory cell 300 (same circuit as shown in FIG. 2) and a read data latch 330 is illustrated. In order to read, the bit lines 302 and 309 are released from the pre-charged voltage at VL level, after then the read word line 310 is asserted to high, while the write word line 301 keeps low. When the first terminal 311 (which is connected to the read word line 310) is reached to VFP level (built-in voltage of p-n-p transistor Q1), p-n-p transistor Q1 is turned on if the storage node 312 of the diode is near ground level. By turning on p-n-p transistor Q1, the collector 313 (floating node) of p-n-p transistor Q1 is raised and reached near the read word line voltage from ground level. At the same time, n-p-n transistor Q2 is turned on, because the collector 313 of p-n-p transistor Q1 serves as the base 313 of n-p-n transistor Q2. Turning on p-n-p transistor Q1 and n-p-n transistor Q2, the emitter 314 (also the first bit line 302) of n-p-n transistor is raised by the current. Thus the first bit line 302 is raised from ground level, where the initial voltage of the bit line 302 is set to ground level by NMOS 333 with pre-charge true (PT) signal, while the NMOS 331 and 332 are turned on. In contrast, the second bit line 309 keeps low during read operation. After then, pre-charge true (PT) signal is lowered to ground level before the read word line 310 is asserted. When the first bit line 302 is reached to the threshold voltage (VTN) of the pull-down NMOS 335, pull-down device 335 is turned on, when the switch 332 is turned on by the inverter 343 which is driven by the latch node 337, where the latch node 337 is set by pre-charge-bar (PB) signal. As a result, a current path is set up from the read word line 310 to the first bit line 302, which is read “1” operation. Hence, the read word line 310 indirectly turns on n-p-n Q2 through p-n-p Q1. In other words, diode access device detects whether the storage node is at forward bias or not. In this manner, the diode access device serves as a sense amplifier when read. When the current path is set up, the read word line voltage is determined by the result of the voltage dividing among the elements, the pull-down NMOS 335, the four-terminal diode, pull-up device of the read word line driver (not shown), and routing resistance.

As a result, the read word line voltage is near the sum of the bit line voltage and built-in voltage of the diode because the pull-down NMOS 335 has low resistance with common gate-drain connection like diode connection, which determines the bit line voltage, and four-terminal diode (including p-n-p Q1 and n-p-n Q2) has lower resistance, where the pull-up device of the read word line driver has high resistance at linear region, and routing resistance is negligible. After then, the current mirror 336 repeats the amount of the bit line current, where the current value can be controlled by the channel width, length, and multiple mirrors. By the current mirror, the pre-charged node 337 is discharged from pre-charged voltage to ground, where the latch node 337 is pre-charged by the PMOS 338 when pre-charge bar (PB) signal is at ground level during standby. After pre-charging, PB signal is de-asserted before the read word line is asserted. Hence, the data output (DO) of the inverter 339 is changed from low to high, and transferred to next stage (not shown). After latching the stored data, feedback inverter 340 and inverter 339 keep the stored data. Simultaneously, the switch 332 is turned off by the output 344 of the inverter 343 (at ground level), thus the data latch cuts off the current path of the bit line after reading data “1”, in order to reduce the active current.

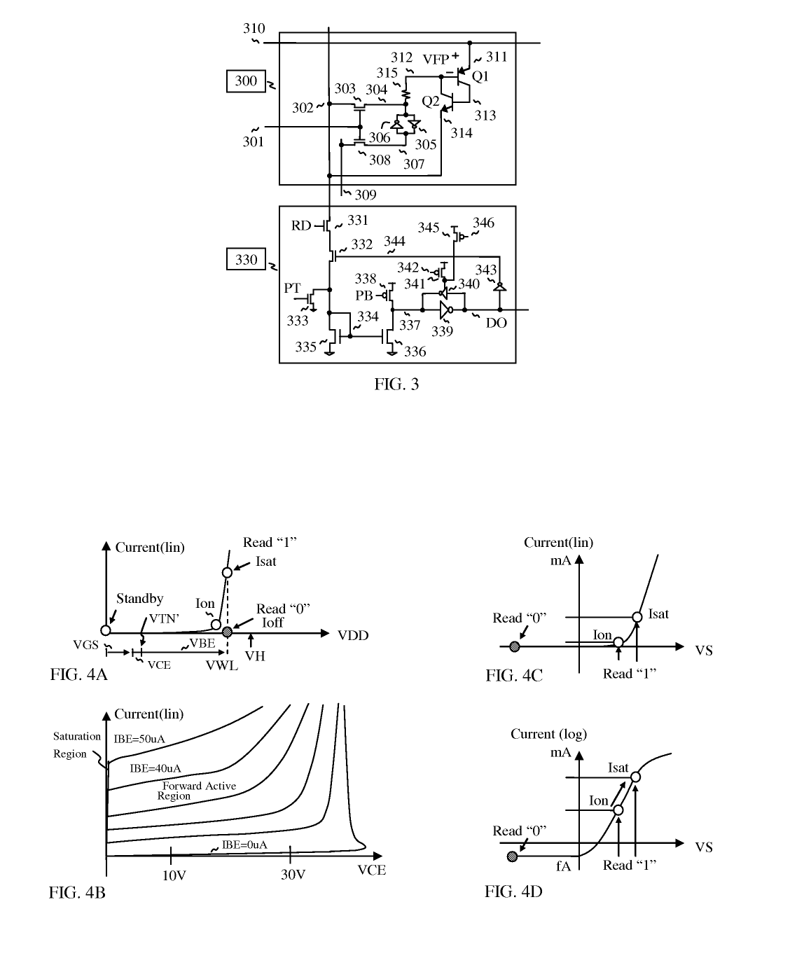

After transferring data output DO, the read word line 310 is de-asserted to VL level to finish the read cycle. By lowering the read word line 310 to VL level, the collector 313 of p-n-p Q1 (also the base 313 of n-p-n Q2) is discharged by the read word line 310, but the read word line can not fully discharge the collector 313, because p-n-p Q1 is turned off when the collector 313 is reached around built-in voltage VFP. The remained charges are swept by the forward bias (from p-type region 313) to n-type region 314 because the read word line does not provide positive charges after de-asserted to VL level and the forward bias leakage current sweeps the remained positive charges. In general, forward bias leakage is much higher than reverse bias leakage. As a result, the diode access device can fully cut off the current path during standby or unselected after the read word line is de-asserted to VL level. In doing so, the unselected cell does not generate any interference or noise when read and write data. Furthermore, the read operation is nondestructive because the storage node 312 is still in forward bias region, but the stored voltage is slightly raised from ground level to VTN+VCE level. Thus, the resistor 315 enhances the storage node 312 of the resistor to reach to VTN+VCE level, while the latch node 304 is less pulled up, because the value of the resistor 315 is much bigger than the turn-on resistance of the pull-down NMOS of the inverter 306. For example, the resistance value is 10 times bigger than the turn-on resistance of the NMOS of the inverter 306, such that the base node 312 is quickly raised by the read word line, which sets up a current path from the read word line to the bit line. In doing so, the latch node 304 keeps almost same voltage before the read word line is asserted. More detailed explanation will be followed in FIGS. 4C and 4D.

During read data “1”, the current mirror 336 repeats the amount of the bit line current. At the same time, the pull-up PMOS of the feedback inverter 340 resists the latch node 337 to be discharged by the current mirror, which means that the current through the current mirror 336 should be higher than that of the pull-up device of the inverter 340. When the supply voltage is high enough, such as 1.2V, the current flow through the bit line is high enough to flip the latch node 337 even though the feedback inverter resists. In order to reduce the operating voltage, a bias voltage is applied to the pull-up device 341 of the feedback inverter, which effectively regulates the pull-up current. When the read word line 310 is asserted, the bias signal 342 is asserted. On the contrary, the slightly strong pull-up device 345 is turned on by the control signal 346, when the read word line is de-asserted, which keeps the stored data after the read word line is de-asserted. In order to reduce the operating voltage, lower built-in voltage is required, where the built-in voltage is determined by the p-n junction of the material. Additionally, lower threshold voltage of the current mirror is required as well. Furthermore, the bias voltage is generated by the dummy cell, which will be explained in FIG. 7.

In order to read data “0”, the read word line 310 is asserted, but p-n-p Q1 is not turned on because the forward bias is not set up from the first terminal 311 to the storage node 312 at high level, where the first terminal 311 is connected to the read word line 310. Hence, read data “0” is quite different from read data “1”. Neither the forward bias is established nor the current path be set up. In doing so, p-n-p Q1 and n-p-n Q2 are turned off. The storage node voltage is not changed, and the bit line voltage is not changed either. And the pre-charged node 337 is not changed because the current mirror 336 does not flow any current. Hence, data output DO keeps VL level. Neither the latch device requires the reference voltage nor wait long discharging time of the bit line. On the contrary, the conventional comparator type sense amplifier compares the difference between the first bit line and the second bit line, thus one of the bit lines should be discharged enough voltage by the cross-coupled inverter latch through the MOS access transistor where the discharging path includes high resistance with the shallow inversion layer of the MOS transistor.

Referring now to FIG. 4A in view of FIG. 3, I-V curve of the memory cell is depicted. By raising the read word line, the diode is turned-on at Ion when the read word line is reached to built-in voltage of the diode. After then, the current is saturated at Isat. During saturation, the read word line voltage (VWL) is determined by three elements, such as the gate voltage (near threshold voltage, VTN) of pull-down NMOS device (335 in FIG. 3), the collector-emitter voltage (VCE) of n-p-n Q2 in FIG. 3 and the base-emitter voltage (VBE) of p-n-p Q1 in FIG. 3. Once the diode is turned on when reading data “1”, the current path is sustained by the feedback loop, which also sustains the read word line voltage (VWL). On the contrary, when reading data “0”, the diode does not flow any current, except Ioff current (reverse bias leakage). And during standby, the read word line is de-asserted to ground level by the row decoder (not shown). Hence, there is no standby current except leakage current.

In FIG. 4B, I-V curve of conventional bipolar transistor is illustrated as a reference. The bipolar transistor's usefulness may be terminated as the collector voltage is increased, which is called “punch-through” or “reach-through” as described in the reference, “Microelectronics: Digital and Analog Circuits and Systems”, pp. 83, Jacob Millman, Ph. D. 1979 MacGraw-Hill, Inc. ISBN 0-07-042327-X, where punch-through is occurred when the base-collector voltage reaches a certain (device specific) value, the base-collector depletion region boundary meets the base-emitter depletion region boundary. When in this state the transistor effectively has no base. The device thus loses all gain when in this state. Thus, punch-through should be avoided having enough base area, or reducing the collector-emitter voltage. In the present invention, punch-through is simply avoided by selecting wide base region or reducing the collector-emitter voltage.

In FIG. 4C, more detailed read operation is illustrated with I-V curve in linear scale. By raising the read word line, the forward bias is set up from the read word line to the storage node of the diode, when the storage node is near ground level. Thus, a current path is established at Ion point, which means that the NMOS pull-down transistor is turned on by the current path. After then, the read word line is raised higher. As a result, the current path is saturated at Isat point, because the read word line is raised by the strong driver. In contrast, the reverse bias is set up when the storage node is at the supply voltage, which is read “0”. Hence, no current path is set up except the reverse bias leakage current.

In FIG. 4D, I-V curve in log scale is illustrated, wherein the current path is established at Ion point, and the current path flows more current at Isat point when the read word line voltage is raised higher. When the storage node voltage is near ground level (VL level), the forward bias is set up, thus the current is increased exponentially from Ion point to Isat point. This graph shows that the diode sets up a current path as long as the forward bias is established, but the amount is different depending on the voltage, which means the strong forward bias can set up higher current flow to the pull-down device. Hence, the high operating voltage can set up higher current path, and achieves fast access time. When the stored voltage is around the supply voltage (VH level), the reverse bias is set up because the read word line voltage is slightly lower than the supply voltage when read, but the reverse bias leakage is less affected depending on the stored charges as long as the storage node voltage is around the read word line voltage, which voltage is near the supply voltage when read.

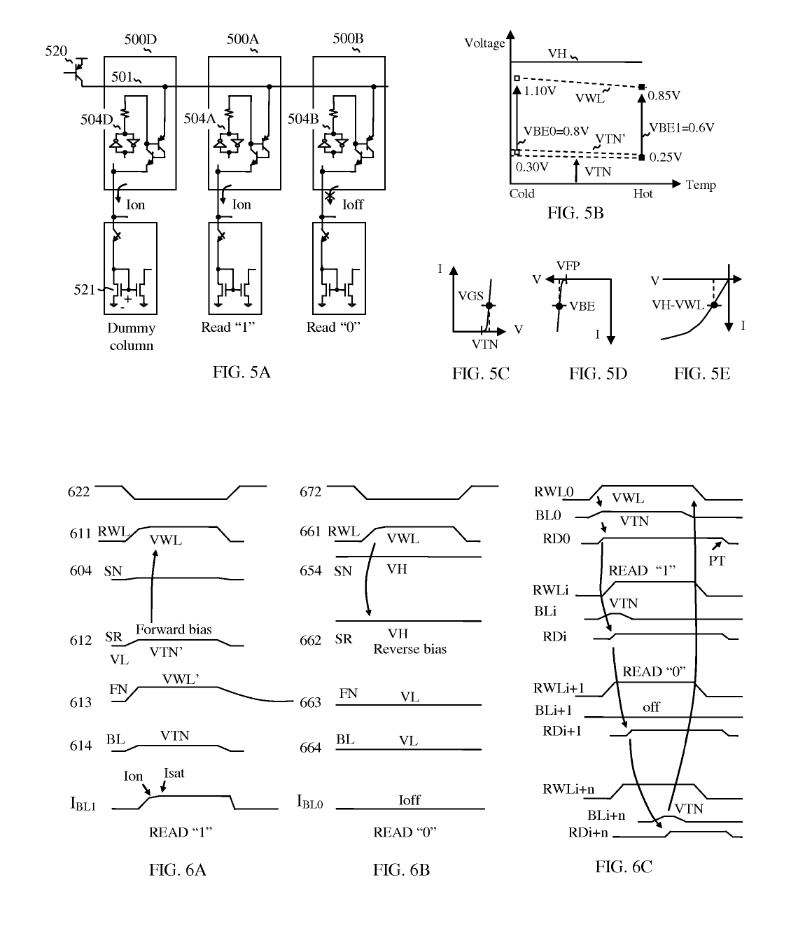

In FIG. 5A, more detailed read path is illustrated as the present invention. In the memory array, multiple memory cells are connected to the read word line 501, such that the memory cell 500A stores data “1” in the storage node 504A, the memory cell 500B stores data “0” in the storage node 504B, and dummy cell 500D stores data “1” in the storage node 504D. When read, at least one memory cell is turned on, in order to sustain almost same voltage of the read word line 501 regardless of the data pattern. In doing so, single or multiple dummy cells are added to limit the read word line voltage, as explained in FIG. 4A. Without dummy cell, the read word line voltage can be reached to VH level by the pull-up device 520 of the word line driver, when all the stored data are “0” because all the memory cells are turned off. In order to apply strong reverse bias during read, the read word line voltage is sustained slightly lower than VH level by turning on at least one dummy cell, and the current does flow through the pull-down NMOS 521.

Thus, the read word line voltage is determined (as VWL in FIG. 5B), such that the read word line voltage is the sum of three elements, such as the gate voltage VGS (near threshold voltage of pull-down NMOS 521), VCE (the collector-emitter voltage of n-p-n Q2 in FIG. 3), and VBE (near built-in voltage of p-n-p Q1 in FIG. 3), where the gate voltage VGS is 0.25˜0.3V range in recent MOS transistor, VCE is lower than 0.1 v which is ignorable with strong bipolar gain, and VBE is 0.6˜0.8V for silicon, for example. In addition, the voltages depend on the ratio among the resistances of three elements. Moreover, the read word line voltage depends on temperature, because threshold voltage of MOS transistor and built-in voltage of bipolar transistor are decreased as temperature is increasing. As shown example in FIG. 5B, the read word line voltage VWL is 1.1V at 0° C. As temperature is increasing, the read word line voltage is decreased to 0.85V at 100° C. More detailed current-voltage curves are illustrated in FIGS. 5C, 5D and 5E. The I-V curve of pull-down NMOS transistor 521 is shown in FIG. 5C, wherein the threshold voltage of NMOS transistor is VTN, and the applied voltage of the transistor is VGS, where VGS level is determined by the current flow including pull-down NMOS, p-n-p-n diode and pull-up PMOS. Thus, VGS level is near threshold voltage of NMOS transistor when the diode is fully turned on and in latching state with the feedback loop, but VGS level is only slightly changed when the current is changed more because the curve is very steep above the threshold voltage of NMOS transistor. The I-V curve of base-emitter of p-n-p transistor is shown in FIG. 5D, wherein built-in voltage (or threshold voltage) of p-n-p Q1 transistor is VFP, and the applied voltage of the transistor is near VBE level, where VBE level is determined by the current flow including pull-down NMOS transistor, p-n-p-n diode and pull-up transistor 520. Thus, VBE level is near built-in voltage, but VBE level is only slightly changed when the current is changed more because the curve is very steep above the built-in voltage of p-n-p Q1 transistor. In FIG. 5E, I-V curve of pull-up device 520 is shown, wherein the applied voltage of pull-up transistor 520 is determined by subtracting the read word line voltage VWL from VH level of the supply voltage, which curve is less steep, thus the applied voltage of pull-up device is varied by the read word line voltage. The applied voltage of pull-up transistor is VH-VWL as shown in FIG. 5E.

And the bit line voltage is near VGS level if the bit line resistance is ignorable, and the collector-emitter voltage VCE of n-p-n Q2 is relatively low because collector current is much higher than the base current when the bipolar transistor is fully turned on in nature. Hence, VCE level is lower, which is ignorable. In this respect, the storage node voltage (VTN′) is very close to VTN level, when the stored data is “1”, where VTN′=VTN+VCE, and VTN′=VWL−VBE as shown in FIG. 5B.

By asserting the read word line 501, the memory cell 500A and 500D are turned on because the forward bias is set up from the read word line 501 to the storage nodes, where the storage node 504A and 504D are near ground level (VL level). After read, the storage nodes of the resistors are raised to VTN′ level by the current flow. And then, the storage node of the resistor is quickly returned to the ground level by the latch, and then the storage node is sustained by the cross-coupled inverter latch as long as the supply voltage is maintained. Hence, the SRAM cell does not require refresh operation.

When the stored data is “0”, there is no current path, such that the memory cell 500B is not turned on because the storage node voltage 504B is slightly higher than the read word line level (VWL), which results in reverse bias. With no current consumption when read “0”, power consumption is reduced. When all the memory cells store data “0”, only dummy cells are turned on, in order to apply a reverse bias for the memory cells storing data “0”. Turning on dummy cells, the read word line voltage is limited lower than VH level as explained above, at VWL level.

Referring now to FIG. 6A in view of FIGS. 5A and 3, timing diagram for read “1” operation is illustrated. In order to start read cycle, the read word line (RWL) 611 is asserted, while the write word line keeps low (not shown). Thus, the read word line voltage is reached to VWL level. When the stored data is “1”, the storage node (SN) 604 is near ground level. By asserting the read word line (RWL) 611, a forward bias is established from the read word line 611 to the storage node of the resistor (SR) 612 which is connected to the storage node (SN) 604 through a resistor. Thus, the storage node of the resistor (SR) 612 is raised by the read word line 611, where the resistor value is much bigger than the turn-on resistance of the latching inverter. And then, the floating node (FN) 613 (which serves as the base 313 of n-p-n Q2 in FIG. 3, and also the collector 313 of p-n-p Q1 in FIG. 3) is raised near word line voltage. At the same time, n-p-n Q2 is turned on, which raises the bit line 614. When the bit line 614 is reached to threshold voltage (VTN) of pull-down NMOS 521 in FIG. 5A, the pull-down NMOS is turned on. The bit line current IBL1 is appeared, such that Ion current is set up at the beginning of the asserting of the read word line. After then, the current path is saturated at Isat, thus, the storage node of the resistor (SR) is raised around VTN′ level, and the bit line keeps around VTN level. While the read word line 611 is enabled, the bias control signal 622 sets up a bias voltage for the feedback inverter as shown 341 FIG. 3. And the control signal 341 in FIG. 3 is disabled after the word line is de-asserted. And then, the control signal 341 turns on the strong pull-up device 345 with another control signal 346 in FIG. 3. In order to reduce the operating voltage for the memory array, the ratio between the current mirror (336 in FIG. 3) and the feedback inverter (340 in FIG. 3) is carefully adjusted, such that the current flow through the current mirror is 10 times higher, because the bit line current is drastically reduced at low voltage, where the bit line current is determined by the built-in voltage of the diode and the threshold voltage of the pull-down NMOS. Furthermore, the current is reduced at cold temperature. In order to reduce the operating voltage and increase the bit line current, germanium diode and Schottky diode can be useful. However, leakage current is relatively higher. Additionally, low threshold MOS transistor is available to reduce the operating voltage, which requires more process steps, such as additional implant mask.

Referring now to FIG. 6B in view of FIG. 5A, timing diagram for read “0” operation is illustrated. The read word line 661 is asserted to start reading data, while the write word line keeps low (not shown). Unlike read “1”, when the read word line 661 is raised, the forward bias is not established between the storage node of the resistor (SR) 662 and the read word line 661, because the storage node of the resistor (SR) 662 is around VH level. Hence, reverse bias is set up. As a result, there is no current path (IBL0) so that there is only leakage current Ioff. Thus, the floating node (FN) 663 keeps ground level with no pull-up current from the p-n-p transistor. Read “0” does not consume the current from the read word line 661 to the bit line 664, which helps to save active power. And the bias control signal 672 does not affect the read “0” operation. After reading data “0”, the storage node is not changed, even though the storage node (SN) is very slightly raised by the diode during read “1”, thus the read operation is nondestructive.

When reading data “1”, the current is established while the word line is turned on. In order to reduce the power consumption, a replica delay signal is generated by the far-end dummy cell, as shown FIG. 6C. And the replica delay signal is returned to the read word line decoder, which signal de-asserts the read word line, wherein the nearest dummy word line RWL0 is asserted first, and next word lines are asserted sequentially, such as RWLi, RWLi+1, and RWLi+n. As a result, the bit lines, BL0, BLi, BLi+1 and BLi+n are sequentially raised by enabling read enable signals, RD0, RDi, RDi+1 and RDi+n. The related schematic is illustrated in FIG. 7.

In FIG. 7, more detailed read path is illustrated, wherein the memory cells 731, 732, 733 and 734 are connected to the read word lines RWL0, RWLi, RWLi+1 and RWLi+n from the read word line driver 719, and the memory cells are also connected to the read data latches 781, 782, 783, and 784 through the bit lines BL0, BLi, BLi+1, and BLi+n, respectively. And the memory cells are connected to the write word line (WWL) which is part of the local row decoder 718.

In order to read data from the memory cells, the pre-charge true (PT) signal and the pre-charge bar (PB) signal are de-asserted, before the read word line is asserted. In doing so, the bit lines BL0, BLi, BLi+1 and BLi+n are floating. And the read enable (RD) signal is asserted to high. At the same time, the read word line (RWL) is asserted to high, while the write word line (WWL) keeps low. By asserting the read word line (RWL), the nearest dummy cell 731 is turned on, which stores data “1” and sets up a current path from the read word line to the read data latch 781. Thus, the current path through the bit line BL0 raises the node 758 near the threshold voltage of the NMOS pull-down device. During read, the PT signal is low, thus the NMOS pre-charge device 751 and 757 are turned off, and the PMOS 753 is turned on. When the signal 758 is reached to the threshold voltage of the NMOS 756, a current path is set up through the PMOS 754 and 755. Hence, the bias voltage is raised by the current repeater circuit 750, where the current flow through the repeater devices 754, 755 and 756 is the same as the bit line current if the NMOS pull-down devices have same width and length. In this manner, the latch node 762 of the (dummy) read data latch 781 is changed from the pre-charged VH level to VL level by the current mirror 761, because the pull-up device of the feedback inverter 759 is, for instance, 10 times weaker than that of the current mirror 761 when the bias signal 752 from the repeater circuit 750 is raised by the PMOS 754, where the pull-up PMOS 754 is 10 times stronger than the current repeater 759, such that 10 parallel devices (or 10 times wider channel) are used with the same channel length for the pull-up PMOS 754. Before the bias signal 752 is raised, the pull-up device 759 is relatively stronger than the current mirror, while the bias signal 752 is near ground level. The advantage of the biased pull-up device 759 is that the comparison between the bit line current and the pull-up current of the feedback inverter is very accurate. Thus, the operating voltage can be reduced and also the bit line current itself can be reduced, in order to save power consumption, which reduces the current loading of the read word line as well. Hence, the read word line driver circuit can be smaller. For example, each bit line current can be reduced lower than 1 uA, thus the pull-up current of the feedback inverter is 0.1 uA. In doing so, wrong latch operation is prevented, because the latch node is not flipped before the bias signal is fully set up. The bias signal 752 is pre-charged to ground level before the read word line is asserted. Hence, the pull-up device of the feedback is very strong, before the bias signal is not set up. And the bias signal 752 is shielded from the adjacent signals to avoid coupling noise. After measuring all the stored data, the replica signal 726 and 727 are returned to the control circuit 725 which turns off the read word line (RWL). With this feedback scheme, the bias signal 752 is floating after the read word line is grounded. In order to sustain the latched data “0” after then, a pull-up device 763 is enabled by a signal 723B which is an inverted signal of the read word line enable 723. The latched data “1” is not affected even though the read word line is de-asserted, because the data “1” is sustained by the NMOS of the feedback inverter.

After establishing the dummy bit line current through the dummy bit line BL0, the dummy latch device 781 keeps the bit line current, in order to maintain the read word line voltage until the far end dummy data latch 784 generates a replica delay signal 727, and one more signal 726 can be generated by another far end dummy column (not shown), which means that the read word line can be controlled by one of dummy data latch, even though a dummy cell has failed. Thus, the inverter output 764 is floating, and NMOS transistor 760 is always on to keep the current path of the nearest dummy column. After the latch node 762 is flipped, the signal is transferred to OR gate 765. And the OR gate 765 generates the read enable (RD0) signal, in order to start measuring the bit line current of the main memory cells, which OR gate receives multiple signals from multiple dummy column. Thus, the replica delay signal RD0 is generated as long as one dummy column works, where only one dummy column BL0 is illustrated for simplifying the schematic. The OR gate 765 includes delay circuits to add time interval for measuring the main memory cell. In doing so, simultaneous current flow through the bit lines are reduced. When the read enable RD0 signal is reached to high, the latch device 782 measures the bit line current. When the bit line is raised by the diode if the stored data is “1”, the latch device 782 sets up a current path, and the current mirror latches the data. Thus the data output of the latch 782 is raised to high. Otherwise, the output keeps low if the stored data is “0”, because the bit line keeps low with no diode current. And the delay circuit 766 generates next read enable signal RDi for the next latch device 783, wherein the AND gate 766 receives RD signal and RD0 signal (from dummy cell), thus the AND gate generates RDi signal through the delay circuit. In this manner, all the bit line currents are measured by the read data latch sequentially with the time interval of the circuits 766 and 767, as long as the delay time is longer than the latching time. When the delay time is faster than the latching time, the read word line loading is increased, which may cause in stuck with no flipping of the rest of the latches 783 and 784. This should be avoided. With the sequential latching scheme, the read word line loading is only a few columns, in terms of the current loading, where each column has a delay circuit. Alternatively, the columns are grouped, and a delay circuit controls a group of columns to reduce area. In this case, the read word line should provide more current.

In order to control the memory cells efficiently, the row decoder 710 includes global row decoder 711 and local row decoder 718. One global row decoder 711 may drive multiple local row decoders, even though one local row decoder 718 is illustrated in FIG. 7 for simplifying the drawing. The global row decoder 711 receives row address through AND gate 712. When the AND gate 712 is selected, next stage AND gates 713 and 715 are activated. Hence, the AND gate 713 is raised to high when the row decoder enable signal 723 is asserted to high, because the output of AND gate 712 is asserted to high before the enable signal 723 is asserted to high. To do so, the read word line control circuit 725 generates the signal 723 with the start signal 724 and feedback signals 726 and 727. The feedback signals are generated by far-end dummy column, in order to detect the completion of measuring of the far-end dummy columns. At least, one far-end dummy column generates a feedback signal. And the AND gate 715 is asserted to high when the write enable signal 717 is activated, which controls the write word line (WWL).

The local row decoder 718 includes two elements AND gate 719 (comprising NAND and inverter) and the AND gate 721, wherein the AND gate 719 generates the read word line (RWL) and the AND gate 721 generates the write word line (WWL), when the local column selector 722 is asserted to high. As shown in FIG. 7, the write word line drives only capacitive loading, but the read word line drives capacitive loading and the current loading through the pull-down transistors of the data latches, 781, 782, 783 and 784. The capacitive loading is simply managed by selecting the total number of the memory cells. However, the read word line loading depends on how many memory cells store data “1”. When all the memory cells store data “1”, the read word line raises all the bit line to the threshold voltage of NMOS pull-down device.

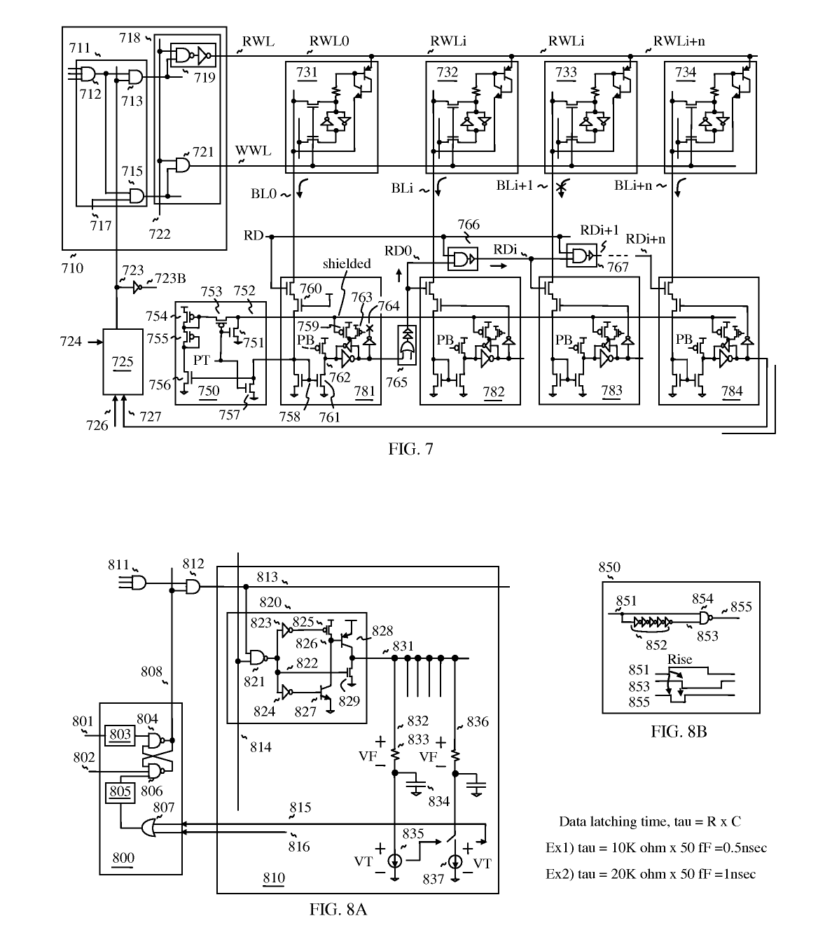

An equivalent circuit of the read path is illustrated in FIG. 8A, wherein the local memory block 810 includes the read word line driver 820, the read word line 831, the dummy bit lines 832 and other bit line 836. The local read word line 831 is raised by the p-n-p transistor 828 to supply high current. When the read word line enable 801 is asserted to high, the pulse generator 803 generates a low pulse during the pre-determined time, such that more detailed pulse generator 850 is illustrated in FIG. 8B. The output 855 generates a low pulse when the input 851 is rising, so that the NAND gate 854 generates a low pulse only if the output 853 of the inverted delay circuit 852 and the input 851 are at high state. In doing so, the pulse generator 803 generates a low pulse. Thus, the read word line control circuit 800 generates a read word line enable signal 808. When the read word line enable signal 808 is asserted to high, the global read word line decoder 812 raises the global read word line 813, because the output of the address decoder 811 is already asserted to high. And the column select signal 814 is also asserted to high. Hence, the NAND gate 821 is activated, such that the output 822 is lowered, the inverter 824 turns on the n-p-n transistor 827. Thus, the base 826 of the p-n-p transistor 828 is turned on, which pulls up the local read word line 831. At the same time, the PMOS transistor 825 is turned off, and also the NMOS 829 is turned off before the p-n-p transistor 828 is turned on. When the p-n-p transistor is turned on, the local read word line 831 is quickly reached to the voltage VF+VT, where VF is built-in voltage of the diode and VT is the threshold voltage (VT) of the NMOS transistor of the data latch, after then the ramping depends on how many cells store data “1”. Thus, the data latching time is the charging time of the bit line. For instance, the charging time (Tau) is the equivalent resistance 833 of the diode (R) multiplied by the bit line capacitance 834 (C), so that the charging time is 0.5 ns when the diode resistance is 10 K ohms and the bit line capacitance is 50 fF, approximately. And for another example, the charging time is ins when the diode resistance is 20 K ohms and the bit line capacitance is 50 fF. In the calculation, the resistance of the read word line is ignored because the p-n-p transistor 828 includes relatively lower resistance.

After the bit lines are charged to the threshold voltage of the NMOS transistor, the pull-down NMOS transistor serves as a current source 835 equivalently, which is a part of the read data latch (781 as shown in FIG. 7), but the next data latch (782 in FIG. 7) waits until the read enable signal RD0 is asserted by the delay circuit (765 in FIG. 7). In this manner, only the current of the dummy bit line BL0 is the current loading of the read word line 831. And then, the next current source 837 of the data latch is turned through the bit line 836 on after the read enable signal RD0 is asserted to high. Thus, all the data are latched sequentially by the delayed read enable signal. At last, the far-end dummy data latch generates a signal to turn off the read word line, as shown 815 and 816. Furthermore, multiple far-end dummy columns generate the replica delay signals, in order to close the read word line even though one of the far-end dummy cell is failed. When the replica delay signals 815 and 816 are arrived, the read word line control circuit 810 de-asserts the read word line enable signal 808, such that the pulse generator 805 generates a low pulse, thus the output of the NAND gate 806 is raised to high. And then, the output of the NAND gate 804 is changed to low, because the output of another pulse generator 803 is already high, as explained above, where the latch circuit including two NAND gates 804 and 806 is reset by the power-up reset signal 802, during power-up, such that the power-up signal 802 is asserted to low during power-up, after then, the power-up signal 802 is always at high. The advantage of using bipolar driver circuit for the decoder is that the strong drive current can be provided by the bipolar transistor and the area of the driver is relatively small. There were many efforts to use the bipolar driver circuits on the wafer as reported, “BiCMOS buffer circuit”, U.S. Pat. No. 5,430,398. However, the prior art of the bipolar driver circuit can provide relatively low current because the base current of the output portion is driven by the MOS transistor. Moreover, the n-p-n transistor is turned off when the output node is reached to VH level—VF level (built-in voltage), which means that the prior art is only useful to drive relatively high supply voltage, such as 5V and 3.3V. In the present invention, the output portion (p-n-p) 828 of the bipolar buffer circuit is also driven by the reverse (n-p-n) type of bipolar transistor 827, and the reverse type of bipolar transistor is enabled by a MOS transistor of the inverter 824, so that the MOS transistor current I1 enables the n-p-n transistor 827, the collector current 120 turns on the p-n-p transistor 828, and the strong collector current 1400 drives the read word line 831. For example, the current flow is amplified to 400 from the MOS drain current I1, if the bipolar collector current gain is 20. And the bipolar transistors can be formed from the same layer for the diode access device, such as deposited polysilicon layer or single crystal layer of the SOI type wafer. In the prior art, the bipolar transistors can not be easily optimized on the conventional bulk CMOS process because all the transistors share the same substrate, such as p-type and n-type substrate.

In the present invention, the diode access device is not sensitive to the strength of the variation of the cross coupled latch, during read. This means that the storage inverter only contributes to set up the initial condition of the storage node of the resistor node (SR) when read, while the prior art of SRAM is sensitive to the strength of the cross-coupled inverter latch because the inverter directly discharges the heavily loaded bit line through the MOS access transistor. In the present invention, there is no need of strong inverter latch to read. Furthermore, the diode also serves as a sense amplifier to detect the initial voltage of the storage node of the resistor (SR) whether it is forward bias or not, when the read word line is asserted to read. After detecting the forward bias, the diode is turned on, which sets up the current path to the bit line. In doing so, the memory yield will be increased by reducing the variation of the inverter strength. In terms of the data retention, the weaker inverter is the better to reduce the retention current. Thus the weak inverter latch has less leakage current during data retention, and the weak inverter latch can set up the initial condition of the diode when read. In this respect, the latch can be formed from thin-film polysilicon or amorphous silicon layer even though those devices can flow less current than single crystal MOS transistor. In contrast, the read path is controlled by the read diode. Hence access time is fast because the diode current is much higher than that of MOS access transistor in the conventional SRAM.

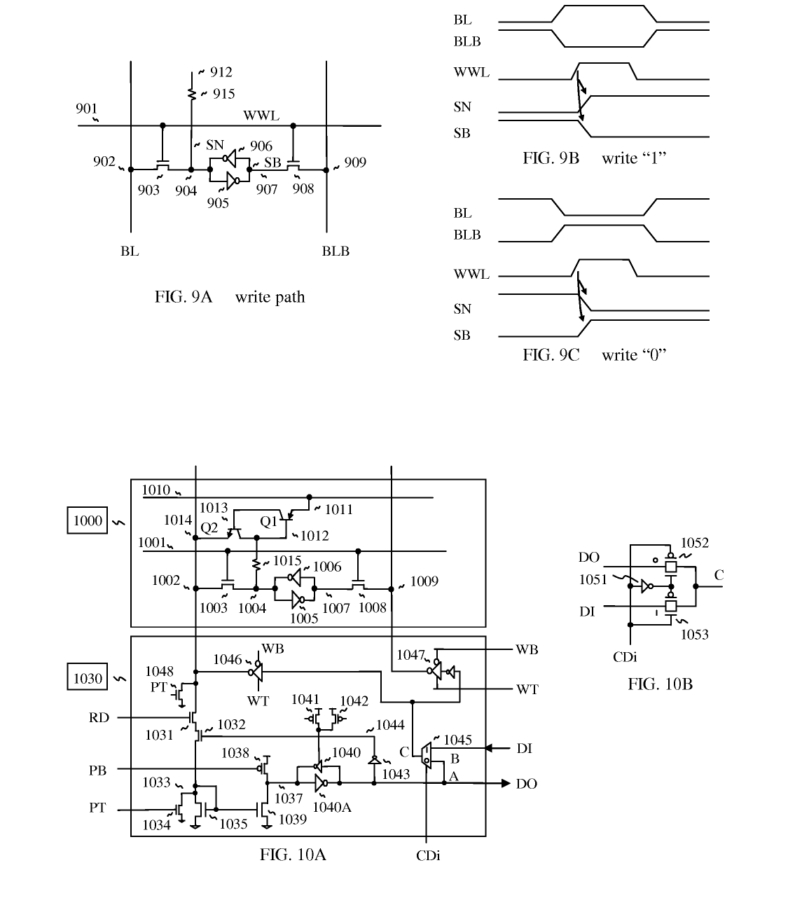

In FIG. 9A, the write path is illustrated. The write circuit is similar to the conventional SRAM with two MOS transistors, wherein the first MOS transistor 903 is turned on by the write word line 901, and the second MOS transistor 908 is turned on by the write word line 901 as well, thus the voltage of the first bit line 902 is transferred to the storage node (SN) 903 and the voltage of the second bit line 909 is transferred to the second storage node (SB) 907. During write, the cross-coupled latch including two inverters 905 and 906 will resist the change of the latch node when the incoming data is negative polarity. And the storage node of the resistor 912 is connected through the resistor 915, which node is controlled by the latch node (SN) during write. In FIG. 9B, the write “1” timing is illustrated, wherein the first bit line (BL) and the second bit line (BLB) are set up before the write word line (WWL) is asserted to high, thus the first storage node (SN) is changed to high and the second storage node (SB) is changed to low. In FIG. 9C, the write “0” timing is illustrated, wherein the first bit line (BL) and the second bit line (BLB) are set up before the write word line (WWL) is asserted to high, thus the first storage node (SN) is changed to low and the second storage node (SB) is changed to high. The write time or flipping time of the storage nodes depends on the resisting force of the latch device, when the bit line driver circuit is strong enough to drive the cross coupled latch through the MOS write device. In other words, the weaker latch is the better to write data quickly. This means that the latch can be formed from the thin-film transistor, such as polysilicon and amorphous silicon. Furthermore the bit line driver (not shown) can be composed of bipolar driving portions (similar circuit to the read word line driver as shown in FIG. 8A), which portions also can be formed from the thin-film layer. And the diode read device detects the voltage of the resistor node 912 during read, as long as the resistor node sustains the stored voltage with reduced numbers of charges.

In FIG. 10A, the read-write circuit and the memory cell are illustrated in order to explain read-modify-write operation, wherein the read-write circuit 1030 is connected to the memory cell 1000 through the bit line 1002. Even though the read operation is nondestructive as explained above, the storage node voltage (SN) is slightly changed after reading data. After then, the storage node is quickly recovered by the latch. Thus, write-back operation is not required, and also refresh operation is not required either because the cross-coupled latch keeps data as long as the supply voltage is sustained.

In the memory array, there are many memory cells which are connected to the bit lines. When the memory array is increased, the numbers of column are more than the external input data. Thus, part of columns receives external data, but the other columns are floating. When the cross-coupled latch is strong enough to absorb the charges from the bit line, the stored data are not changed as the conventional SRAM write operation. However, the floating columns (unselected columns) are not safe to sustain the stored data when the cross-coupled latch is extremely weak with thin-film transistors. In order to avoid wrong flip for the unselected cells, the write operation executes actually read-modify-write operation, alternatively.

For executing the read-modify-write operation, the read word line 1010 is asserted to read the data in the memory cell 1000, thus the stored data in the memory cell is transferred to the latch node 1037 through the bit line 1002. The latch node 1037 is pre-charged to high by the PMOS transistor 1038 when the pre-charge bar (PB) signal is low, and the MOS switches 1031 and 1032 are turned on, before the read word line 1010 is asserted. When the stored data is “1”, the current path is set up through the diode, wherein the diode includes four-terminals, the first terminal 1001 is connected to the read word line 1010, the second terminal 1012 is connected to the storage node of the resistor 1015, the third terminal 1013 is floating, and the fourth terminal 1014 is connected to the first bit line 1002. Hence, the current mirror 1039 repeats the amount of the current flow of the pull-down NMOS transistor 1035 through the common node 1033. At this time, the pre-charge devices 1034, 1038, and 1048 are turned off. During read, the current limiter 1041 is turned on in order to regulate the pull-up current of the feedback inverter 1040. And the pull-up transistor 1042 sustains the pull-up after the current limiter is turned off. Thus, the stored data is latched to the latch node 1037 with inverters 1040A and 1040, and the output node DO is asserted to high. After then, the read-out data is transferred to the write driver circuit 1046 and 1047 through the selector circuit 1045 when the column decoder signal CDi is at low, wherein more detailed selector circuit 1045 is illustrated in FIG. 10B, the CDi signal is inverted by the inverter 1051 to switch the transmission gates 1052 and 1053. When CDi signal is low, DO signal is transferred to output node C through the transmission gate 1052. And when CDi signal is high, DI signal is transferred to output node C through the transmission gate 1053.

In order to restore the data for the unselected cells, the write driver circuit 1046 and 1047 are enabled by the write enable signal WT and WB signals, and then the write word line 1001 is asserted to high to turn on the MOS transistor. In doing so, the first storage node 1004 is fully discharged to ground level and the second storage node 1007 is charged to near high level to restore data “1”. When the stored data is “0”, the reverse voltages are stored in the storage nodes, respectively. In contrast, the read-modify-write operation changes the write data through the selector circuit 1045, such that the column decoder signal CDi is asserted to high and the external data input DI is transferred to the bit lines. Hence, the external data input DI is stored in the memory cell 1000.

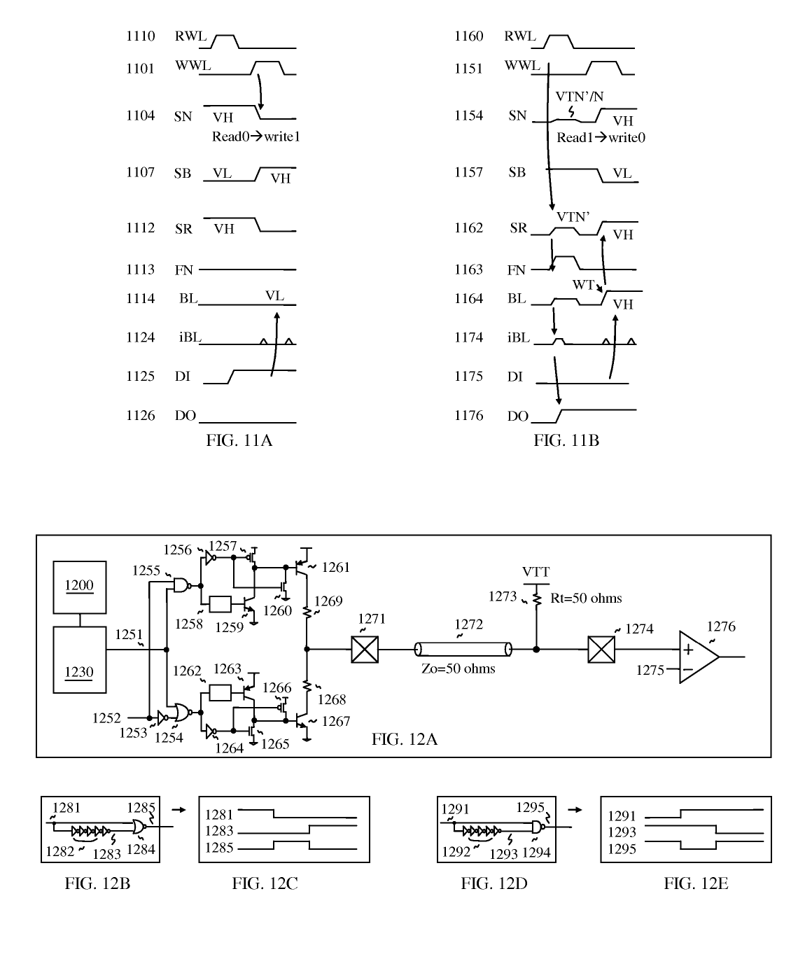

In FIG. 11A, read-modify-write operation (for read “0” and write “1”) is illustrated. When the second terminal 1112 (the resistor node (SR) of the latch) keeps near supply voltage, the read word line (RWL) 1110 sets up the reverse bias, because the storage node of the resistor (SR) is connected to the first storage node (SN) 1104, while the second storage node (SB) 1107 is not connected to the diode. Thus, the floating node (third terminal) 1113 remains at low because the diode is turned off. And the bit line voltage 1114 is not changed, which does not change the output DO from the pre-charge level. As a result, the read “0” operation is completed. And the read word line is de-asserted. After then, the write word line (WWL) 1101 is asserted to high to write the input data (DI) 1125, such that the input data (DI) is set up before the write word line 1101 is asserted, and then the write word line is asserted. Thus, the first storage node 1104 and the second storage node 1107 are flipped by the bit lines, respectively.

In FIG. 11B, read-modify-write operation (for read “1” and write “0”) is illustrated. When the second terminal 1162 (the resistor node (SR) of the latch) keeps near ground voltage, the read word line (RWL) 1160 set up the forward bias, because the storage node of the resistor (SR) is connected to the first storage node (SN) 1154. Thus, the diode sets up a current path, which raises the floating node (third terminal) 1163 near the read word line voltage. And the bit line voltage 1164 is raised to the threshold voltage of the NMOS transistor, which changes the output DO from the pre-charge level to high. As a result, the read “1” operation is completed. And the read word line is de-asserted. After then, the write word line (WWL) 1151 is asserted to high to write the input data (DI) 1175, such that the input data (DI) is set up before the write word line 1151 is asserted, and then the write word line is asserted. Thus, the first storage node 1154 and the second storage node 1157 are flipped by the bit lines, respectively. Thus, the read operation and the write operation are independently executed.

In FIG. 12A, the whole read path including the output driver circuit is illustrated, wherein the memory cell 1200 (1000 in FIG. 10A) and the read-write circuit 1230 (1030 in FIG. 10A) are connected to the output driver circuit including p-n-p pull-up 1261 and n-p-n dull-down 1267, and the output pad 1271 is connected to the receiver circuit 1276 through the transmission line 1272, where the multiplexers between the output driver and the read-write circuit 1230 are omitted for simplifying the schematics. The data in the memory cell 1200 is latched to the read data latch 1230. And then, the data output 1251 is transferred to NAND gate 1255 and NOR gate 1254 which are part of the output driver circuit. After arriving the data output 1251, the output enable signal 1252 is asserted to high to transfer the data output. When the read data is “1”, the NAND gate 1255 generates a logic low, which raises the output of inverter 1256 to high, thus the PMOS 1257 is turned off and the NMOS 1260 is turned on. At the same time, a pulse generator 1258 generates a high pulse to turn on the n-p-n transistor 1259, wherein more detailed schematic of the pulse generator 1258 is illustrated in FIG. 12B, and the timing diagram is illustrated in FIG. 12C. When the input signal 1281 is lowered, an inverter chain 1282 is generates a delayed signal 1283, and the NOR gate 1284 generates a high pulse based on the delay, where the delay time is longer than the transition time of the output node 1271. In this manner, the p-n-p output driver 1261 provides enough current to drive the heavily loaded output trace, when the base current is driven by the n-p-n transistor 1259. Simultaneously, the NMOS 1260 provides a weak base current. Hence, the NMOS 1260 keeps turn-on state of the p-n-p transistor after the strong n-p-n transistor is turned off by the delay circuit. And the resistor 1269 makes the pull-up path more linear when driving the output node. And the termination resistor 1273 is added in order to reduce reflection which is caused by the long transmission line 1272, while the short transmission line generates less reflection. The receiver circuit 1276 receives the data output from the memory cell through the receiving side output node 1274, and the receiver 1276 compares the data output 1274 to the reference signal 1275 which is near the half voltage of the supply voltage.

The falling path is composed of reverse configuration from the rising path, wherein the NOR gate 1254 is raised to high when the output 1251 is low and the output (enable signal) of the inverter 1253 is asserted to low. The p-n-p transistor 1263 is turned on by a low pulse generator 1262, wherein detailed schematic of the low pulse generator is illustrated in FIG. 12D and the timing diagram is illustrated in FIG. 12E, the input signal 1291 is raised to high, an inverter chain 1292 is generates a delayed signal 1293, and the NAND gate 1294 generates a low pulse based on the delay, where the delay time is longer than the transition time of the output node 1271. In doing so, the p-n-p transistor 1263 provides enough base current to the n-p-n transistor 1267. At the same time, inverter 1264 is asserted to low, thus the NMOS 1265 is turned off and the PMOS 1266 is turned on, where the PMOS 1266 keeps the output node 1271 after the strong p-n-p transistor 1263 is turned off by the delay circuit. In order to transfer the data output to the next chip, the bipolar output driver should drive relatively high capacitive loading and the current loading through the transmission line. Thus multiple pull-up and pull-down devices can be added to match the impedance of the transmission line, alternatively.

Using bipolar transistors as the output driver portion has many advantages, such that the speed is fast and the area is reduced. There are many prior arts to use the bipolar transistor as the output driver, as published, “BiCMOS TTL output driver”, U.S. Pat. No. 5,038,058, but as explained above, the bipolar transistors can not be easily optimized on the conventional bulk CMOS process because all the transistors share the same substrate. But now in the present invention, the bipolar transistors can be separately optimized because the bipolar transistors are independently formed from the MOS transistor with deposited thin-film layers.

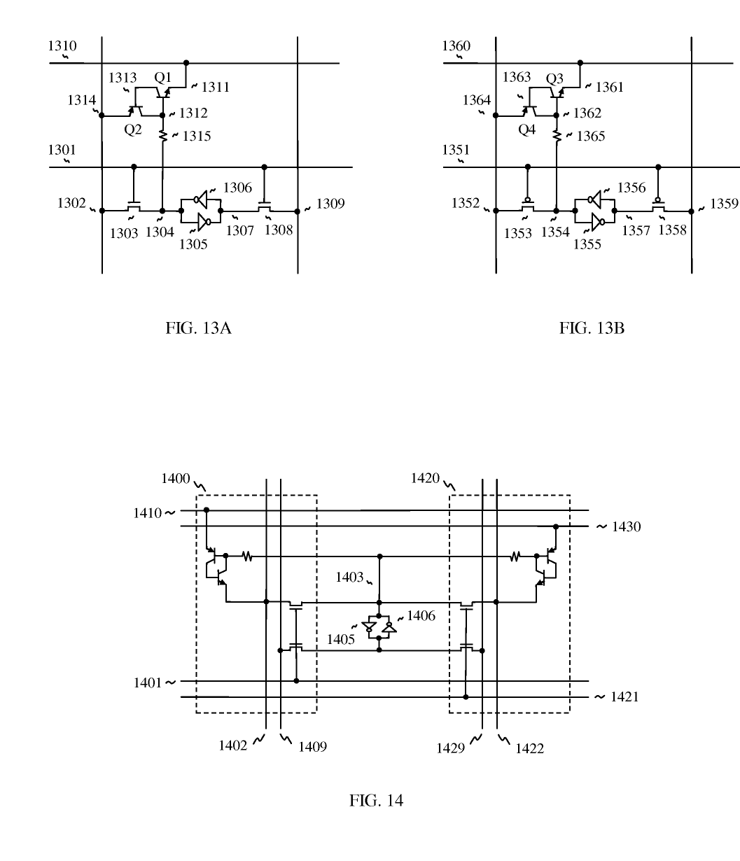

In FIG. 13A, an alternative configuration including an n-p-n-p diode is depicted, wherein the diode is illustrated as an n-p-n transistor Q1 and a p-n-p transistor Q2. And the read diode is composed of the first terminal 1311, the second terminal 1312, the third terminal 1313 and the fourth terminal 1314. The first terminal is connected to the read word line 1310, the second terminal is connected to the resistor 1315, and the fourth terminal is connected to a bit line 1314. The storage device is the same circuit as shown in FIG. 2, wherein the write word line 1301 controls the MOS write devices 1303 and 1308, the cross-couple latch device 1305 and 1306 is connected to the MOS write devices, respectively. And the storage node 1304 is connected to the resistor 1315. During read, the read word line 1310 is asserted to low, and the bit line 1302 (also 1314) is pulled down by the read word line when the stored data is “1”. Otherwise, the bit line 1302 keeps high when the stored data is “0”. During write, the bit line 1302 is asserted to high, the negated bit line 1309 is asserted to low, in order to stored data “1”, and then the write word line 1301 is asserted to high. Otherwise, the bit lines are asserted to inverse polarity to write data “0”.

In FIG. 13B, an alternative configuration including an n-p-n-p diode and PMOS transfer gates is depicted, wherein the diode is illustrated as an n-p-n transistor Q3 and a p-n-p transistor Q4. And the read diode is composed of the first terminal 1361, the second terminal 1362, the third terminal 1363 and the fourth terminal 1364. The first terminal is connected to the read word line 1360, the second terminal is connected to the resistor 1365, and the fourth terminal is connected to a bit line 1364. The write word line 1351 controls the PMOS write devices 1353 and 1358, the cross-couple latch device 1355 and 1356 is connected to the PMOS write devices, respectively. And the storage node 1354 is connected to the resistor 1365. During read, the read word line 1360 is asserted to low, and the bit line 1352 (also 1364) is pulled down by the read word line when the stored data is “1”. Otherwise, the bit line 1362 keeps high when the stored data is “0”. During write, the bit line 1352 is asserted to high, the negated bit line 1359 is asserted to low, in order to stored data “1”, and then the write word line 1351 is asserted to low. Otherwise, the bit lines are asserted to inverse polarity to write data “0”.

In FIG. 14, an example embodiment to implement multi-port memory is illustrated, wherein multiple access devices share a cross-coupled latch including two inverters 1405 and 1406. The access devices 1400 and 1420 are independently accessed. Thereby the storage node 1403 is connected by a metal line, in order to remove p-n diode effect between the two access devices. Thus there is no interference when one of the access devices is activated by the read word line 1410 or 1430, because the storage node 1403 is reverse-biased for the unselected access device, as long as unselected read word line and bit line keep ground level. In doing so, many access devices can be connected to a latch, such that the access device 1400 is selected by the read word line 1410 and the write word line 1401 with the bit line pair 1402 and 1409, and the access device 1420 is selected by the read word line 1430 and the write word line 1421 with the bit line pair 1422 and 1429. The read and write operation are the same as that of single port RAM as explained above, but unselected word line and bit line keep VL level while selected word line and bit line are asserted. During read, the current path is set up from the selected word line to the selected bit line, when the stored data is “1” otherwise the current path is not set up.

Additionally, in FIG. 15, an example embodiment to implement CAM (content addressable memory) as the present invention is illustrated. There are two memory cells and two compare circuits in a CAM cell. Read-write operation for the memory cells is the same as single port memory as explained above. And CAM operation is added in order to compare the stored data and the incoming data referred as comparand. In detail, a CAM is a storage device that is particularly suitable for matching functions because it can be instructed to compare a specific pattern of comparand data with data stored in an associative CAM array. A CAM can include a number of data storage locations, each of which can be accessed by a corresponding address. Functionality of a CAM depends at least in part on whether the CAM includes binary or ternary CAM cells. Ternary CAM cells are mask-per-bit CAM cells that effectively store three states of information, namely a logic “1” state, a logic “0” state, and a don't care state for compare operations. Ternary CAM cells typically include a second memory cell that stores local mask data for the each ternary CAM cell. The local mask data masks the comparison result of the comparand data with the data stored in the first memory cell such that, when the mask bit has a first predetermined value (a logic “0”, for example) its compare operation will be masked so that the comparison result does not affect the match line. The ternary CAM cell offers more flexibility to the user to determine on an entry-per-entry basis which bits in a word will be masked during a compare operation. There are prior arts using the conventional SRAM, “SRAM based refresh-free ternary CAM”, U.S. Pat. No. 6,331,961. But the process technology of the conventional SRAM reaches to the scaling limit within the current CMOS process. Thus the invented memory cell including the diode read device and the MOS write device is used for the CAM application in the present invention, which realizes high-density and high-speed CAM.

Detailed schematic is illustrated as shown in FIG. 15. The memory cell (same circuit as shown in FIG. 2) 1500 and 1510 store data in the storage node (SB) 1507 and 1517, respectively. Thus, the positive data are stored in the second storage node (SB), while the negative data are stored in the first storage node (SN). The emitter 1501 and 1511 are connected to the read word line 1506, and the MOS write devices are connected to the write word line 1501. Compare circuits 1521 and 1522 including NMOS transistor M1 and M2, M3 and M4 share a match line 1541 (ML).

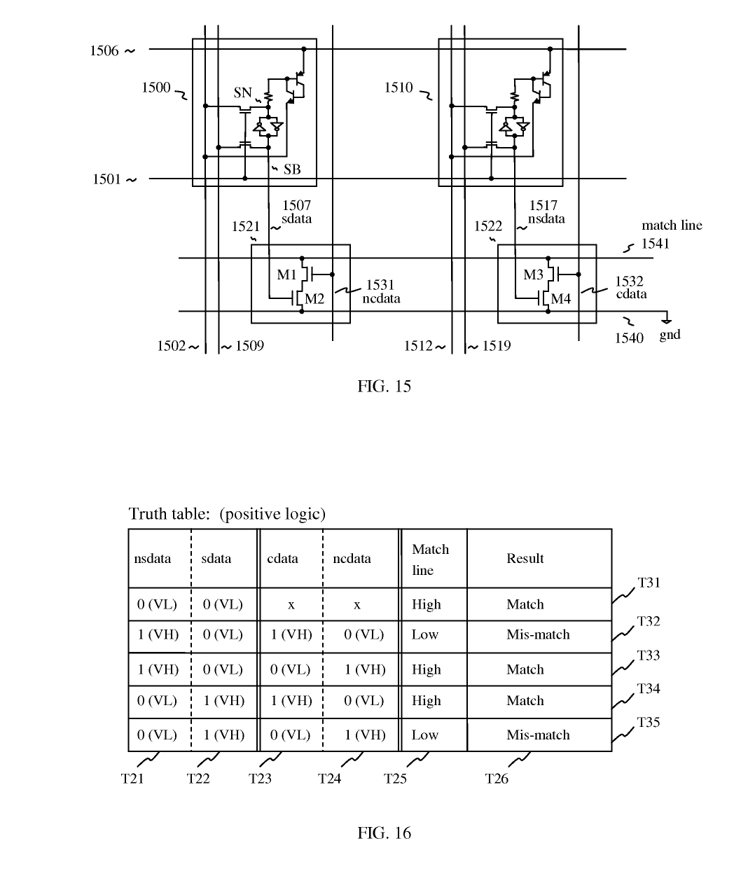

Referring now to FIG. 16 in view of FIG. 15, a truth table is shown summarizing the behavior of CAM cell in relation to signal states maintained by various elements within CAM cell in accordance with the present invention, wherein the compare circuits are configured by the NMOS M1 to M4. Thus, the signal polarities of the internal nodes are non-inverted. First column T21 lists binary states of “0” (at VL) and “1” (at VH) that can be stored in storage node 1517 (namely nsdata) of the memory cell 1510; second column T22 lists binary states of “0” and “1” that can be stored in storage node 1507 (namely sdata) of the memory cell 1500. Third column T23 lists the ternary states that can be maintained in one of the complement compare data lines, namely cdata which is the signal 1532. Fourth column T24 lists the ternary states that can be maintained in the other complement compare data line, namely ncdata which is the signal 1531. Fifth column T25 lists “low” and “high” as the two available voltage levels for match line 1541 mL. Finally, sixth column T26 lists “match” and “mismatch” as the two possible results for comparing states of ncdata line 1531 and cdata line 1532 with the states of CAM cell.

Continuing with FIG. 16 in view of FIG. 15, row T31 indicates masked case where sdata 1507 and nsdata 1517 are “0” (at VL) which makes match line to stay the pre-charge level at logic high, regardless of the compare data, such that the stored data “0” has potential VL level which turns off NMOS compare circuit M2 and M4, rows T32-T33 both indicate that “0” state of CAM cell is represented by “0” (at VL) of memory cell 1500, and “1” (at VH) of latch memory cell 1510. In row T32, because state “1” of cdata line 1532 does not match state “0” of CAM cell (sdata 1507), match line ML is driven “low” to indicate a mismatch of the data key and the stored value of CAM cell. In row T33, because state “0” (at VL) of cdata line 1532 matches state “0” (at VL) of CAM cell (sdata 1507), match line ML is driven “high” to indicate a partial match of the comparand and the stored value of CAM.

Continuing still with FIG. 16 in view of FIG. 15, rows T34-T35 both indicate that “1” state of CAM cell is represented by “1” (at VH) of latch memory cell 1500 and “0” (at VL) of CAM cell 1510. In row T34, because state “1” (at VH) of cdata line 1532 matches state “1” (at VH) of CAM cell, match line 1541 mL is driven “high” to indicate a partial match of the comparand and the stored value of CAM cell. In row T35, because state “0” (at VL) of cdata line 1532 does not match state “1” (at VH) of CAM cell, match line ML is driven “low” to indicate a mismatch of the comparand and the stored value of CAM cell.

Methods of Fabrication

The memory cell includes a small cross-coupled inverter latch as a storage device, a coarse MOS transistor as a write device, and a diode as a read device, with no new materials. Thus, the steps in the process flow should be compatible with the current CMOS manufacturing environment as published as the prior arts, such as U.S. Pat. No. 5,734,179, No. 5,320,975, No. 7,151,696, No. 6,104,045, No. 6,229,161, No. 6,940,761, and No. 6,943,083, in order to form the memory cell with a four-terminal diode. In this respect, there is no need of describing too much detailed process flow to form the memory cell, such as width, length, thickness, temperature, forming method or any other material related data. Instead of describing those details, the present invention focuses on illustrating the new memory cell structures which are practical and mass producible.

The memory cells can be formed from thin-film layer within the current CMOS process environment, as long as the reverse bias leakage and the oxide leakage are controllable. Furthermore, the memory cell can be formed in between the routing layers. In this manner, fabricating the memory cell is independent of fabricating the peripheral circuits. In order to form the memory cell in between the metal routing layers, LTPS (Low Temperature Polysilicon) can be used, as published, U.S. Pat. No. 5,395,804, U.S. Pat. No. 6,852,577 and U.S. Pat. No. 6,951,793. The LTPS has been developed for the low temperature process (around 500 centigrade) on the glass in order to apply the display panel, according to the prior arts. Now the LTPS can be used as a coarse MOS transistor for write path, and also as a p-n-p-n diode for read path. Generally, polysilicon diode can flow less current than single crystal silicon diode, but the polysilicon diode can flow more current than MOS transistor, because the diode can flow the current through the whole junction while the MOS transistor can flow the current through the shallow inversion layer by the gate control. During write, the polysilicon MOS transistor drives the storage node of the weak latch, such that the latch device of the invented memory cell is relatively smaller than the conventional SRAM, thus the coarse MOS transistor can drive the small latch to store the charges. In consequence, multiple memory cells can be stacked over the substrate with no very thin oxide layer. The insulator for the storage inverter may be thicker than that of MOS transistor for control circuits. During polysilicon process, the MOS transistor in the control circuit and routing metal are less degraded.

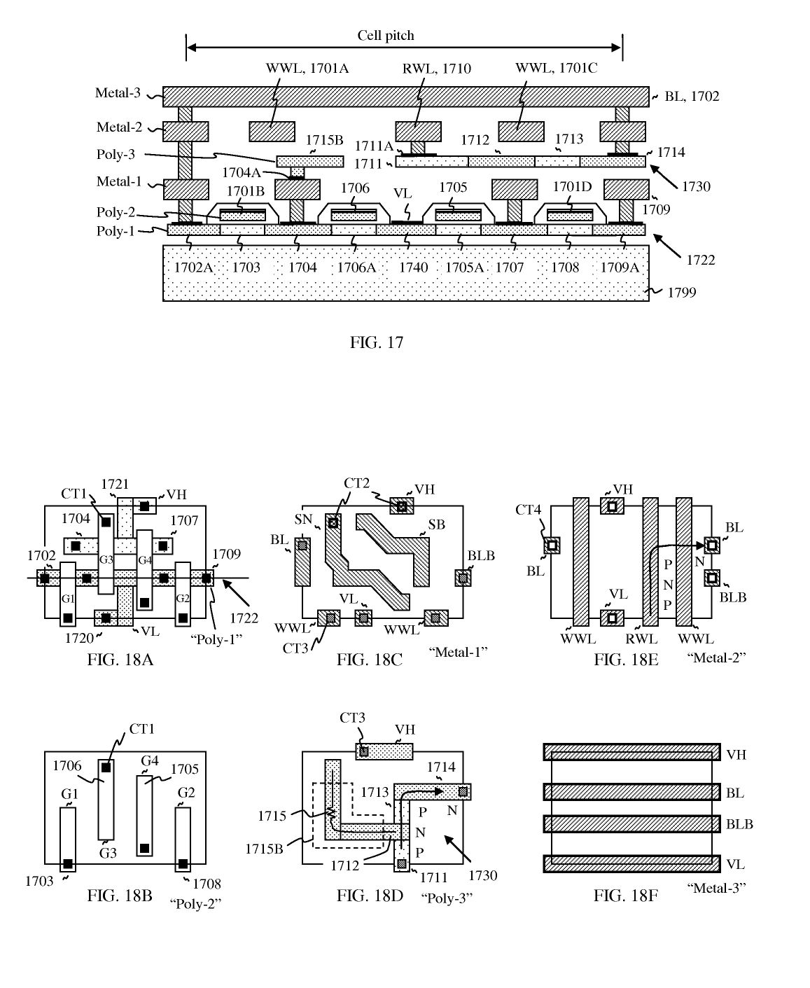

In FIG. 17, an example SRAM cell structure is illustrated. The read diode is formed on the write MOS transistor and the cross-coupled latch, wherein the diode includes four-terminals, the first terminal 1711 is connected to the read word line 1710 through the ohmic contact region (silicide) 1711A, the second terminal 1712 is connected to the resistor node 1715B (more detailed drawing is shown in FIG. 18D), and the third terminal 1713 is attached to the bit line 1714. For easy of understanding, the diode is well positioned in the direction 1730, but actual layout is slightly different, which will be explained in FIG. 18A to 18F. The write MOS transistors are formed from the poly-1 layer on the wafer 1799, wherein the first write MOS transistor is composed of the gate 1701B, the drain/source 1702A is connected to the bit line 1702 through conduction layers, and the source/drain 1704 is connected to the resistor 1715A through contact region 1704A, and the second write MOS transistor is composed of the gate 1701D, the drain/source 1709A is connected to the second bit line 1709, and the source/drain 1707 is connected to the gate 1706 of the latch through metal-1 layer (not shown). The NMOS gate 1705 and 1706 serve as the pull-down device of the latch, where the node 1705A and 1706A serve as the body for the NMOS transistors, respectively, and the ground node 1740 is connected to the NMOS transistors. And the NMOS transistors are shown from the direction 1722. The poly-1 layer is used as the active region of the MOS transistors, the poly-2 layer serves as the gate region, and the poly-3 layer serves as the diode region. The metal-1 layer is used as the routing layer to connect the gates and the active regions, the metal-2 layer is used as the read word line, the write word line, and via region for the bit lines and the power supply lines, and the metal-3 layer is used as the bit lines and power supply lines. The memory cell can be formed on the SOI wafer with additional steps of the conventional SOI process environment. Alternatively, the memory cell is stacked over the wafer 1799, which means that the memory cell does not use the surface of the wafer.

In FIG. 18A to 18F, the layers for the example memory cell structure in FIG. 17 is illustrated. In FIG. 18A, the top view of the active region (poly-1) and the gate region (poly-2) are shown, the gate G1 and G2 configure NMOS write devices, the gate G3 and G4 configure the cross-coupled latch, and the latch is supplied by the power supply node 1721 at VH level and the ground node 1720 at VL level. The drain/source of the NMOS transistor including the gate G1 is serves as the bit line 1702, and the drain/source of the NMOS transistor including the gate G2 is serves as the second bit line 1709. The drain/source of the MOS transistors including the gate G3 serves as the storage node 1704, and the drain/source of the MOS transistors including the gate G4 serves as the second storage node 1707. The first contact region (CT1) is formed on the active regions and the gate regions, respectively.

In FIG. 18B, the gate regions are illustrated again, in order to clarify the poly-2 gate regions, wherein the gates G1 (1703) and G2 (1708) configure the write MOS transfer transistors, and the gates G3 (1706) and G4 (1705) configure the cross-coupled latch. The first contact region CT1 is formed on the poly-2 gate regions.

In FIG. 18C, the metal-1 regions are illustrated, wherein the metal-1 layer is deposited on the contact-1 CT1 region as shown in FIGS. 18A and 18B, thus the metal-1 storage node (SN) is connected to the storage node 1704 in FIG. 18A, and the metal-1 second storage node (SB) is connected to the second storage node 1707 in FIG. 18A. The contact-2 CT2 regions connect the poly-3 region as shown in FIG. 8D, hence, the storage node (SN) is connected to the resistor 1715, and the power supply node is connected to the active region 1721 in FIG. 18A through the metal-1 region.

In FIG. 18D, the poly-3 regions are illustrated, wherein the read diode device is composed of the p-type first terminal 1711, the n-type second terminal 1712, the p-type third terminal 1713, and the n-type fourth terminal 1714. The second terminal 1712 is connected to the resistor 1715 which is composed of un-doped polysilicon region 1715B.

In FIG. 18E, the metal-2 regions are illustrated, wherein the read word line (RWL), the write word line (WWL), the bit line (BL), the second bit line (BLB), and the power supply lines are connected to the poly-3 region in FIG. 18D through the contact-3 CT3 region and the metal-2 region in FIG. 18C through the contact-3 CT3 region, while the contact-2 region is used to connect the poly-3 to the metal-1 region. And the contact-4 CT4 regions are used to connect the metal-2 region and the metal-3 regions as shown in FIG. 18F.

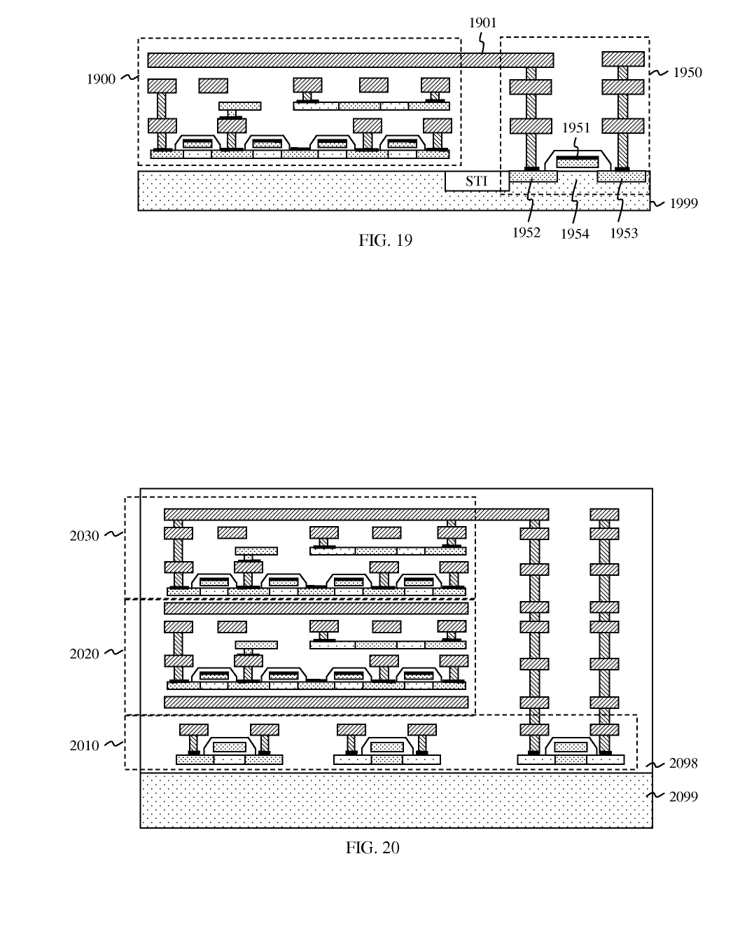

In FIG. 19, the memory cell 1900 is formed on the wafer 1999, wherein the memory cell structure is the same structure shown in FIG. 17. And the bit line 1901 is connected to the MOS transistor 1950. Thus, the MOS transistor is composed of the gate 1951, the drain/source 1952/1953, and the body 1954, where the bulk 1999 serves as the body 1954. And the MOS transistor is separated by the shallow trench isolation (STI). Thus, fabricating the memory cells on the bulk wafer is compatible with the current CMOS process with low-temperature polysilicon layers.

In FIG. 20, the memory cells 2020 and 2030 are stacked over the control circuits 2010, wherein the upper memory cell 2030 is formed on the lower memory cell 2020, and the lower memory cell 2020 is formed on the control MOS transistors 2010, which transistors can be part of decoders or read data latches. The whole circuits are formed on the isolation layer 2098 which is formed on the wafer 2099.

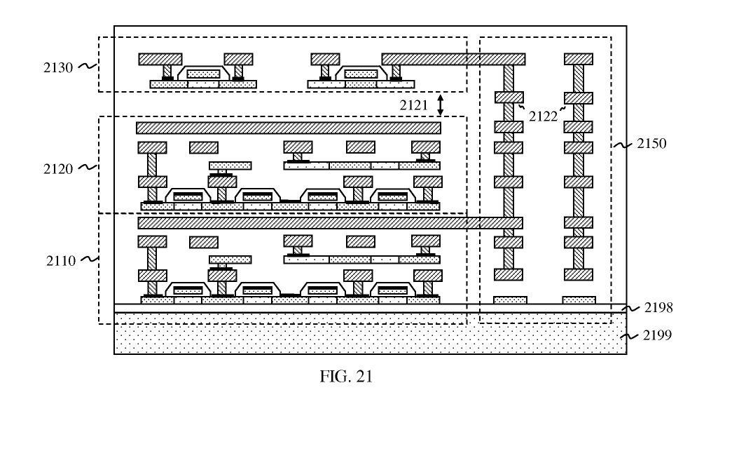

In FIG. 21, the memory cells are stacked under the control circuits as an alternative embodiment, wherein the upper memory cell 2120 is formed on the lower memory cell 2110, and the upper memory cell 2120 is formed under the control MOS transistors 2130 as an example, which transistor may be part of decoders or read data latches. Alternatively, the MOS transistors 2130 are formed on the flatter surface when the insulation layer 2121 is thicker than others. And the plugs 2122 are used as a buffer region for the contacts. Hence, the control circuits are stacked over the memory cells, which enable to connect the output node to the external connector (not shown), such as package lead frame and the ball grid array, more efficiently. As explained above, the heavily loaded control signals are driven by bipolar buffers which are also formed from the thin-film layers. Thus, the control circuits can be stacked over the wafer with an insulator because there is no need for fabricating high-performance MOS transistor on the surface of the wafer. Consequently, the whole chip can be fabricated on the isolation layer on the wafer. In doing so, the wafer serves only as a supporter. Thereby, any types of wafer can be a supporter to reduce the wafer cost, such as silicon wafer, quartz wafer, ceramic wafer, glass, metal and so on.

Various diodes can be used as the read access device, such as silicon, germanium, compound-semiconductor, and metal-semiconductor, as long as the reverse bias leakage is controllable.

The foregoing descriptions of specific embodiments of the invention have been presented for purposes of illustration and description. They are not intended to be exhaustive or to limit the invention to the precise forms disclosed. Obviously, many modifications and variations are possible in light of the above teaching. The embodiments were chosen and described in order to explain the principles and the application of the invention, thereby enabling others skilled in the art to utilize the invention in its various embodiments and modifications according to the particular purpose contemplated. The scope of the invention is intended to be defined by the claims appended hereto and their equivalents.

1. A memory device, comprising:
a memory cell which includes a four-terminal diode as a read device wherein the first terminal is connected to a read word line, the second terminal is connected to a storage device through a resistor, the third terminal is floating, and the fourth terminal is connected to one of two bit lines; and two MOS transistors as a write device wherein the first MOS transistor is connected to a (positive) bit line, the second MOS transistor is connected to a (negative) bit line, and the gates of MOS write devices serve as a write word line; and a latch including two cross-coupled inverters as the storage device; and one node of the storage device is connected to the first MOS transistor and another node of the storage device is connected to the second MOS transistor; and
a memory array, wherein main memory cells configure main columns, dummy memory cells configure dummy columns; and the first dummy column generates the first delay signal for enabling the main columns, after the read word line is enabled; and the far end dummy column generates the second delay signal to disable the read word line; and
a peripheral circuit including a row decoder which controls the read word line and the write word line; and a read data latch wherein a latch node is connected to a current mirror, a feedback inverter and a pre-charge device; and the latch node is pre-charged by a pre-charge device during standby; when reading data “1”, the current mirror repeats the bit line current, thus the current mirror changes the latch node, after then, the bit line current is cut off by the output of the latch node, otherwise the latch node keeps the pre-charged voltage when reading data “0”; and an output driver receives the output of the latch node and transfers the received data to the output pad.

2. The memory device of claim 1, wherein the diode includes four terminals, the first terminal is p-type, the second terminal is n-type, the third terminal is p-type, and the fourth terminal is n-type.

3. The memory device of claim 1, wherein the diode includes four terminals, the first terminal is n-type, the second terminal is p-type, the third terminal is n-type, and the fourth terminal is p-type.

4. The memory device of claim 1, wherein the diode is formed from silicon including polysilicon, amorphous silicon and stretchable silicon, germanium, compound semiconductor, and metal to form a Schottky diode.

5. The memory device of claim 1, wherein the diode is formed on the storage device and the write device.

6. The memory device of claim 1, wherein the resistor is formed from polysilicon or amorphous silicon.

7. The memory device of claim 1, wherein the current mirror of the read data latch includes lower threshold MOS transistor than that of control circuit in the chip.

8. The memory device of claim 1, wherein the feedback inverter of the read data latch includes a current source which limits the current flow through the feedback inverter to have lower current than that of the current mirror when read data “1”, where the first dummy column sets up a current path which generates a bias voltage for regulating the current source of the feedback inverter.

9. The memory device of claim 1, wherein the read word line driver includes the first bipolar transistor and the second bipolar transistor; and the first bipolar transistor provides the base current of the second bipolar transistor; and the second bipolar transistor drives the read word line.

10. The memory device of claim 1, wherein the output driver includes the first bipolar transistor and the second bipolar transistor; and the first bipolar transistor provides the base current of the second bipolar transistor; and the second bipolar transistor drives the pull-up portion of the output node; and the third bipolar transistor and the fourth bipolar transistor; and the third bipolar transistor provides the base current of the fourth bipolar transistor; and the fourth bipolar transistor drives the pull-down portion of the output node.

11. The memory device of claim 1, wherein the memory cells are formed in between the routing layers.

12. The memory device of claim 1, wherein the memory cells are formed on the peripheral circuit.

13. The memory device of claim 1, wherein multiple memory cells are stacked.

14. The memory device of claim 1, wherein the peripheral circuit is formed on the silicon substrate, such as the conventional bulk wafer, the compound semiconductor wafer or the SOI (Silicon-on-Insulator) wafer.

15. The memory device of claim 1, wherein the peripheral circuit is formed on the substrate, such as, a quartz wafer, a ceramic wafer, a glass, or a metal.

16. The memory device of claim 1, wherein the storage device is shared by multiple access devices including the read diode and the write MOS transistors, in order to configure multi port memory.

17. The memory device of claim 1, wherein the peripheral circuit includes at least one compare circuit to configure a content addressable memory as an additional component; and the compare circuit includes the first transistor set and the second transistor set, wherein the first signal set couples to control a conduction state of the first transistor set and the second signal set couples to control a conduction state of the second transistor set, wherein the first signal set includes stored data in the memory cell and the second signal set includes comparand data from an input device; and at least one compare circuit coupled among the memory cells and at least one match line to receive first and second signal sets and affect a logical state of the match line in response to a predetermined logical relationship between the first and second signal sets.
